(19) United States
(12) Patent Application Publication
(10) Pub. No.: US 2009/0294943 A1
(43) Pub. Date: Dec. 3, 2009

(54) Stacked structure of integrated circuits having space elements

(75) Inventors: Sheng-Hui Chien, Chu-Nan (TW); Chung-Chiao Pai, Chu-Nan (TW); Yu-Wen Liu, Chu-Nan (TW)

Correspondence Address: BACON & THOMAS, PLLC, 625 SLATERS LANE, FOURTH FLOOR, ALEXANDRIA, VA, 22314-1176, US

(73) Assignee: Kun Yuan Technology Co., Ltd., Chu-Nan (TW)

(21) Appl. No.: 12/382,208

(22) Filed: Mar. 11, 2009

(30) Foreign Application Priority Data
Jun. 2, 2008 (TW) 097120467

(51) Int. Cl. H01L 23/50

(52) U.S. Cl. 257/686; 257/E23.079

(57) ABSTRACT

A stacked structure of integrated circuits having spacer elements includes a substrate, a spacer element, a lower-layer integrated circuit, an upper-layer integrated circuit, and a molding layer. The substrate includes an upper surface on which the spacer element and the lower-layer integrated circuit are arrayed with each other. The lower-layer integrated circuit includes a solder-pad region and a non-solder-pad region adjacent to the spacer element. The upper-layer integrated circuit is disposed on the spacer element, and covers partly over the non-solder-pad region of the lower-layer integrated circuit. Therefore, the overall height of the stacked structure of integrated circuits can be lowered, making the packaging process simplified, the manufacturing process more stable, and the yield rate of production will be raised. Since the inlet end of the wire is electrically connected to the solder pad of the upper-layer integrated circuit, the height of the packaging can be reduced, and so the whole height of the stacked structure of integrated circuits.

### BACKGROUND OF THE INVENTION

1. Field of the Invention

The present invention relates to a stacked structure of integrated circuits having spacer elements, and more particularly, to a structure adapted for stacking multi-layer integrated circuit chips.

2. Description of Related Art

Along with innovation of technologies, electronic products are demanded to be lighter, thinner, shorter, and smaller. As such, electronic products are required to be developed following this trend. Conventionally, integrated circuits are laid out in a two-dimensional manner, namely, all the integrated circuits are disposed on a same plane. This manner, though simple in manufacturing processes, always results in bulky electronic components, hardly reaching to consumers' expectation.

Further, along with advancement of technologies, a measure in stacking the integrated circuits into two layers, an upper-layer integrated circuit and a lower-layer integrated circuit, has been developed. This measure has solved the problem of bulky electronic components, as arranged in the two-dimensional manner mentioned above, and has greatly reduced the overall size of the electronic components. This, however, ends up with another serious problem that when the integrated circuits are stacked up with each other, the upper-layer integrated circuit will likely affect arrangement of wires of the lower-layer integrated circuit. Referring to FIG. 1, a cross-sectional view illustrating a conventional stacked structure of integrated circuits, the stacked structure comprises a substrate 9, two-layer integrated circuits 7,8 stacked above the substrate 9, and a spacing layer 81 interposed between the two-layer integrated circuits 7,8. By means of the spacing layer 81, the spacing between the two-layer integrated circuits 7,8 can be maintained at a certain distance. This will leave a significant space for the lower-layer integrated circuit 8 for an arrangement of wires. Nevertheless, such layout for the integrated circuits 7,8 cannot fit all types of electronic components, including an integrated circuit structure of memory cards. Besides, the whole arrangement of the integrated circuits 7,8 increases its height because of the spacing layer 81. This increase of height becomes a setback for the pursuit of lighter, thinner, shorter, and smaller electronic products.

It is understood, therefore, that to effectively reduce the overall height of the stacked structure of integrated circuits, and to simplify packaging processes of the integrated circuits so as to make manufacturing processes thereof more stable, have been of urgent need for industries.

### SUMMARY OF THE INVENTION

The present invention is to provide a stacked structure of integrated circuits having spacer elements, comprising a substrate, a spacer element, a lower-layer integrated circuit, an upper-layer integrated circuit, and a molding layer. The substrate includes an upper surface on which pluralities of first and of second bonding points are provided. The spacer element is disposed on the upper surface of the substrate, where the spacer element has a specific height. The lower-layer integrated circuit is disposed on the upper surface of the substrate and is arrayed at one side of the spacer element. The lower-layer integrated circuit includes a solder-pad region full of plural first solder pads, and a non-solder-pad region adjacent to the spacer element. The first plural solder pads are, through plural first wires, electrically connected with the plural first bonding points of the substrate, respectively. The lower-layer integrated circuit has another height which is less than the specific height of the spacer element.

The upper-layer integrated circuit is disposed on the spacer element, and covers partly over the non-solder-pad region of the lower-layer integrated circuit. The upper-layer integrated circuit includes a plurality of second solder pads, wherein the plural second solder pads are, through plural second wires, electrically connected with the plural second bonding points of the substrate, respectively. Further, the molding layer is packaged on the upper surface of the substrate and wraps up the lower-layer integrated circuit, the upper-layer integrated circuit, the spacer element, the plural first wires, and the plural second wires. Therefore, the overall height of the stacked structure of integrated circuits, according to the present invention, can be lowered, that the packaging process of the integrated circuits be simplified and the manufacturing process thereof more stable, and that the yield rate of production be raised.

Further, the spacer element may include a base layer and thermosetting resin layers each provided at top and underneath of the base layer, respectively. The base layer may be of polyimide base layer; or on the other hand, the base layer may be of Si dummy. The thermosetting resin layers may be of epoxy resin layers.

According to the present invention, the spacer element may include a thermosetting resin layer mixed with a plurality of spacer bodies including Polytetrafluoroethene spherical balls. Of course, the spacer bodies are not necessarily spherical, and other shapes, such as oval, polygonal, or equivalents, will do, so long as the spacer bodies can sustain the upper-layer integrated circuit.

Preferably, according to the present invention, the lower-layer integrated circuit may be a controlling integrated circuit chip, while the upper-layer integrated circuit be a memory integrated circuit chip. In the present invention, each of the second wires has an outlet end and an inlet end, where the outlet end is connected with the second bonding point of the substrate, while the inlet end with the second solder pad of the upper-layer integrated circuit. In terms of wire bonding, the wire is bound from the outlet end of the second bonding point of the substrate, upward, to the inlet end of the second solder pad of the upper-layer integrated circuit. Since the inlet end of the wire is electrically connected to the solder pad of the upper-layer integrated circuit, the height of the packaging can be reduced, and so the whole height of the stacked structure of integrated circuits.

Other objects, advantages, and novel features of the present invention will become more apparent from the following detailed descriptions when taken in conjunction with the accompanying drawings.

### BRIEF DESCRIPTION OF THE DRAWINGS

FIG. 1 is a cross-sectional view illustrating a conventional stacked structure of integrated circuits;

FIG. 2 is a top view illustrating a stacked structure of integrated circuits according to the present invention;

FIG. 3 is a cross-sectional view taken along cutting line A-A of FIG. 2;

FIG. 4 is a schematic view illustrating a spacer element according to a first embodiment of the present invention; and

FIG. 5 is a schematic view illustrating a spacer element according to a second embodiment of the present invention.

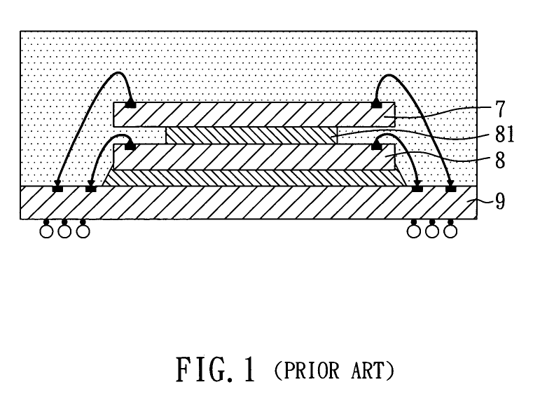

### DETAILED DESCRIPTION OF THE PREFERRED EMBODIMENTS

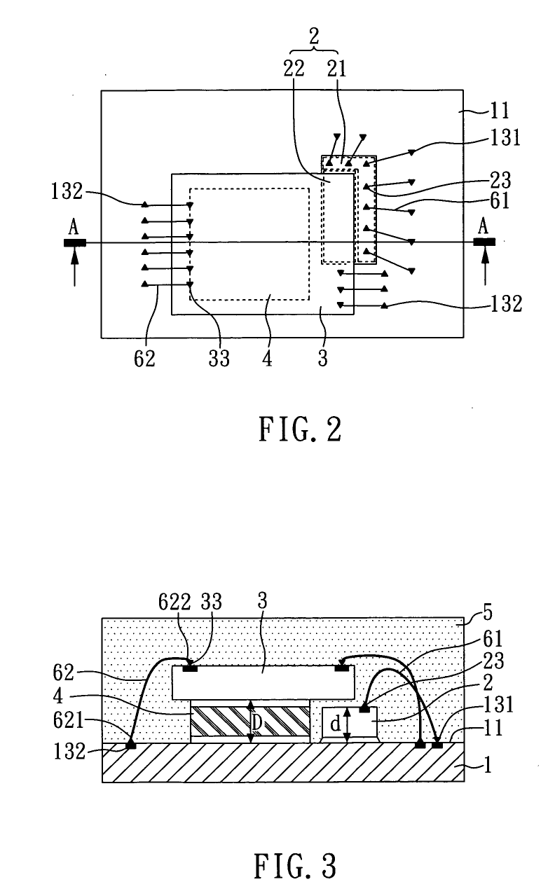

Referring to FIG. 2, a schematic view illustrating a stacked structure of integrated circuits according to the present invention, and to FIG. 3, a cross-sectional view taken along cutting line A-A of FIG. 2, the stacked structure according to the present invention is adapted for stacking all types of integrated circuits, but the following description is specifically given for a stacked structure of memory card integrated circuits. The stacked structure according to the present invention, as shown in FIG. 3, comprises a substrate 1 including an upper surface 11 on which various circuit wires are laid out, and as such, a plurality of first and of second bonding points 131,132 are provided. However, the number of the bonding points 131,132 will depend on demands, unlike the number shown in the drawings.

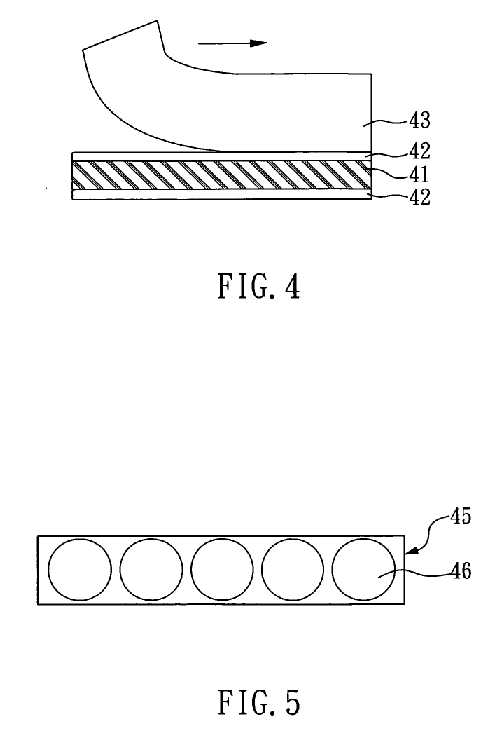

Further, as shown in FIG. 3, there is a spacer element 4 disposed on the upper surface 11 of the substrate 1, where the spacer element 4 has a specific height D. Now referring to FIG. 4, a schematic view illustrating a spacer element according to a first embodiment of the present invention, the spacer element 4 includes a base layer 41 and thermosetting resin layers 42 each provided at top and underneath of the base layer 41, respectively. A cover film 43 is provided at top of the upper thermosetting resin layer 42, where the cover film 43 has to be peeled off before use of the spacer element 4. In the present embodiment, the base layer 41 may be of polyimide base layer (while in the other embodiment, as shown in FIG. 5, the base layer may be of Si dummy). The thermosetting resin layers 42 provided at top and underneath of the base layer 41, respectively, refer to epoxy resin layers, where the epoxy resin layers 42, due to its characteristics of curing and thermosetting, can be adhered to the substrate 1 after baking thereof and becomes hardened so as to provide sufficient strength.

In the present invention, as shown in FIG. 3, a lower-layer integrated circuit 2, referred as a controlling integrated circuit chip, is fixed directly on the upper surface 11 of the substrate 1 and is arrayed at one side of the spacer element 4. As shown in FIG. 2, the lower-layer integrated circuit 2 includes a solder-pad region 21 full of plural first solder pads 23, and a non-solder-pad region 22 adjacent to the spacer element 4. The plural solder pads 23 are, through plural first wires 61, electrically connected with the plural first bonding points 131 of the substrate 1, respectively. The lower-layer integrated circuit 2 has another height d, as shown in FIG. 3, which is less than the height D of the spacer element 4.

Further, an upper-layer integrated circuit 3, referred as a memory integrated circuit chip, as shown in FIG. 2, is stacked on the spacer element 4, and covers partly over the non-solder-pad region 22 of the lower-layer integrated circuit 2. The upper-layer integrated circuit 3 includes a plurality of second solder pads 33, wherein the plural second solder pads 33 are, through plural second wires 62, electrically connected with the plural second bonding points 132 of the substrate 1, respectively.

It should be noted that each of the second wires 62 has an outlet end 621 and an inlet end 622, where, during a packaging process, a wire bonding starts from an outlet end 621 of the second bonding point 132 of the substrate 1, upward, and eventually the inlet end 622 is connected with the second solder pad 33 of the upper-layer integrated circuit 3.

The wire bonding on the memory integrated circuit chips of memory cards is different from that of the conventional art in that the conventional art starts the wire bonding from upper-layer memory integrated circuit chips, downward, to the bonding points of the substrate, whereas in the present invention, the wire bonding starts from the bonding points of the substrate, upward, to the upper-layer memory integrated circuit chips. This is because the solder pad of the memory integrated circuit chip normally has a greater dimension, so that when the wire bonding starts from the second bonding point 132 of the substrate 1, upward, to the larger second solder pad 33, the solder points of the inlet end 622 will hardly get diffused and never effect neighboring solder pads for a short circuit. As such, the wire bonding according to the present invention can raise yield rate of production.

Further, for most cases of wire bonding, the outlet end 62 is far beyond the inlet end 622 in terms of height and angle of wiring. Therefore, in the present invention, the outlet end 621 has a greater height for being electrically connected with the second bonding point 132 of the substrate 1 located below, and that it is necessary for the inlet end 622 to have a less height for being connected with the second solder pad 33 of the upper-layer integrated circuit 3, such that the overall height of the stacked structure of integrated circuits according to the present invention can be lowered. This will avoid a risk of wire exposure, simplify packaging process, and make the manufacturing process more stable. Besides, subject to the condition that each integrated circuit chip has the same thickness, in the present invention, more space will be available to stack, upward, more layers of chips and thus multiply the volume.

As shown in FIG. 3, a molding layer 5 is provided, through a molding process, to package and wrap up integrally the lower-layer integrated circuit 2, the upper-layer integrated circuit 3, the spacer element 4, the plural first wires 61, and the plural second wires 62 on the upper surface 11 of the substrate 1 so as to provide an electrical insulation and protection on the stacked structure of integrated circuits according to the present invention.

Further referring to FIG. 5, a schematic view illustrating a spacer element according to a second embodiment of the present invention, the spacer element 4 may be a whole thermosetting resin layer 45 mixed with a plurality of spacer bodies 46. In the present embodiment, the spacer bodies 46 are mixed with Polytetrafluoroethene spherical balls, or so-called Teflon® balls, such that diameters of the balls can sustain a sufficient height for the layer 45. Of course, the spacer bodies 46 may be of other shapes such as oval, polygonal, or equivalents.

Although the present invention has been explained in relation to its preferred embodiments, it is to be understood that many other possible modifications and variations can be made without departing from the scope of the invention as hereinafter claimed.

What is claimed is:

1. A stacked structure of integrated circuits having spacer elements, comprising:
a substrate, including an upper surface on which a plurality of first and of second bonding points are provided;
a spacer element, being disposed on the upper surface of the substrate, and having a specific height;
a lower-layer integrated circuit, being disposed on the upper surface of the substrate and being arrayed at one side of the spacer element, wherein the lower-layer integrated circuit includes a solder-pad region full of plural first solder pads and a non-solder-pad region adjacent to the spacer element, and wherein the first plural solder pads are, through plural first wires, electrically connected with the plural first bonding points of the substrate, respectively, and wherein the lower-layer integrated circuit has another height which is less than the specific height of the spacer element;
an upper-layer integrated circuit, being disposed on the spacer element and covering partly over the non-solder-pad region of the lower-layer integrated circuit, wherein the upper-layer integrated circuit includes a plurality of second solder pads which, through plural second wires, are electrically connected with the plural second bonding points of the substrate, respectively; and
a molding layer, being packaged on the upper surface of the substrate and wrapping up the lower-layer integrated circuit, the upper-layer integrated circuit, the spacer element, the plural first wires, and the plural second wires.

2. The stacked structure of integrated circuits having spacer elements as claimed in claim 1, wherein each of the second wires has an outlet end and an inlet end, the outlet end is electrically connected with the second bonding point of the substrate and the inlet end with the second solder pad of the upper-layer integrated circuit.

3. The stacked structure of integrated circuits having spacer elements as claimed in claim 1, wherein the spacer element includes a base layer and thermosetting resin layers each provided at top and underneath of the base layer, respectively.

4. The stacked structure of integrated circuits having spacer elements as claimed in claim 3, wherein the base layer is a polyimide base layer.

5. The stacked structure of integrated circuits having spacer elements as claimed in claim 3, wherein the base layer is a Si dummy.

6. The stacked structure of integrated circuits having spacer elements as claimed in claim 3, wherein the thermosetting resin layers are epoxy resin layers.

7. The stacked structure of integrated circuits having spacer elements as claimed in claim 1, wherein the spacer element includes a thermosetting resin layer mixed with a plurality of spacer bodies.

8. The stacked structure of integrated circuits having spacer elements as claimed in claim 7, wherein the plural spacer bodies includes Polytetrafluoroethene spherical balls.

9. The stacked structure of integrated circuits having spacer elements as claimed in claim 1, wherein the lower-layer integrated circuit is a controlling integrated circuit chip.

10. The stacked structure of integrated circuits having spacer elements as claimed in claim 1, wherein the upper-layer integrated circuit is a memory integrated circuit chip.
